(19) United States
(12) Patent Application Publication
(10) Pub. No.: US 2021/0018368 A1
(43) Pub. Date: Jan. 21, 2021

(54) TEMPERATURE SENSING APPARATUS AND TEMPERATURE SENSING SYSTEM USING THE SAME

(71) Applicants: SK hynix Inc., Icheon-si Gyeonggi-do (KR); HJS ENG CO., LTD., Yongin-si Gyeonggi-do (KR)

(72) Inventors: Tae Ho LEE, Cheongju-si Chungcheongbuk-do (KR); Kwang Mun LEE, Seoul (KR); Du Cheal HWANG, Yongin-si Gyeonggi-do (KR)

(73) Assignees: SK hynix Inc., Icheon-si Gyeonggi-do (KR); HJS ENG CO., LTD., Yongin-si Gyeonggi-do (KR)

(21) Appl. No.: 16/664,579

(22) Filed: Oct. 25, 2019

(30) Foreign Application Priority Data
Jul. 16, 2019 (KR) 10-2019-0085692

(51) Int. Cl. G01J 5/06; G01K 7/16; G01J 5/10

(52) U.S. Cl. CPC G01J 5/06; G01J 2005/068; G01J 5/10; G01K 7/16

(57) ABSTRACT

A temperature sensing apparatus may include a body, a tube combined with the body, and a temperature sensor. The temperature sensor is configured to measure a temperature of an object, in the tube, without being in contact with the object. The body may include an air chamber formed adjacent to a temperature sensing region of the object.

### CROSS-REFERENCE TO RELATED APPLICATION

The present application claims priority under 35 U.S.C. § 119(a) to Korean application number 10-2019-0085692, filed on Jul. 16, 2019, in the Korean Intellectual Property Office, which is incorporated herein by reference in its entirety.

### BACKGROUND

### 1. Technical Field

Various embodiments may generally relate to a clamp type, non-contact temperature sensing apparatus and a temperature sensing system using the same.

### 2. Related Art

A semiconductor device may be manufactured using various kinds of fabrication apparatuses. The fabrication apparatuses may include a cleaning apparatus. In order for the cleaning apparatus to etch a wafer at the optimal rate, while having an improved cleaning capacity, monitoring and controlling, in real time, a temperature of a fluid, such as ultrapure water and various kinds of chemicals flowing through a per-fluoro-alkoxy (PFA) tube, may be very important.

According to related arts, the temperature of the fluid in the tube may be measured by directly contacting a temperature sensor with the fluid. This manner may cause frequent failures of the temperature sensor, chemical contaminations due to a corrosion of a metal in the temperature sensor, etc.

Further, the temperature of the fluid in the tube may be obtained from a temperature of the PFA tube. However, because the PFA tube may have a low thermal conductivity, the temperature of the PFA tube may differ greatly from the real temperature of the fluid.

Thus, accurately measuring the temperature of the tube and preventing the chemical contamination in the tube may be required.

### SUMMARY

In example embodiments of the present disclosure, a temperature sensing apparatus may include a body and a temperature sensor. The temperature sensor may be configured to measure a temperature of an object, in the tube, without being in contact with the object. The body may include an air chamber formed adjacent to a temperature sensing region of the object, and a tube-combining groove formed in the body to be combined with the tube.

In example embodiments of the present disclosure, a temperature sensing system may include a temperature sensing apparatus and a temperature calculating apparatus. The temperature sensing apparatus may be configured to measure a surface temperature of an object, by detecting infrared ray energy emitting from the object, and to measure an environment temperature of a temperature sensing region of the object. The temperature calculating apparatus may be configured to apply the surface temperature and the environment temperature of the object to a real temperature calculation criteria to calculate a real temperature of the object.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a view, illustrating a temperature sensing apparatus, in accordance with example embodiments;

FIG. 2 is a cross-sectional view, illustrating a temperature sensing apparatus combined with a tube, in accordance with example embodiments;

FIGS. 3 and 4 are views, illustrating a temperature sensing apparatus, in accordance with example embodiments;

FIG. 5 is a view, illustrating a temperature sensing apparatus by tube sizes, in accordance with example embodiments;

FIG. 6 is a view, illustrating a temperature sensing system, in accordance with example embodiments; and

FIG. 7 is a control block diagram, illustrating a temperature sensing system in accordance, with example embodiments.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present invention as defined in the appended claims.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles and spirit of the present invention.

It will be understood that when an element is referred to as being “connected” or “coupled” to another element, it can be directly connected or coupled to the other element or intervening elements may also be present. In contrast, when an element is referred to as being “directly connected” or “directly coupled” to another element, no intervening elements are present.

It will be understood that when an element is referred to as being “between” two elements, it can be the only element between the two elements, or one or more intervening elements may also be present.

The terms used in the present application are merely used to describe particular embodiments, and are not intended to limit the present disclosure. Singular forms in the present disclosure are intended to include the plural forms as well, unless the context clearly indicates otherwise. It will be further understood that terms such as “including” or “having,” etc., are intended to indicate the existence of the features, numbers, operations, actions, components, parts, or combinations thereof disclosed in the specification, and are not intended to preclude the possibility that one or more other features, numbers, operations, actions, components, parts, or combinations thereof may exist or may be added.

Example embodiments provide a temperature sensing apparatus that may be capable of accurately measuring a temperature of an object in a tube.

Example embodiments also provide a temperature sensing system using the above-mentioned temperature sensing apparatus.

According to example embodiments, the clamp-on type temperature sensor may measure the temperature of the object in the tube using the infrared ray in the non-contact manner.

Therefore, parts of the temperature sensor in the tube might not be chemically corroded so that a lifespan of the temperature sensor may be extended.

Further, the measured temperature of the object in the tube may have improved reliability by correcting an emissivity of the measured temperature of the object.

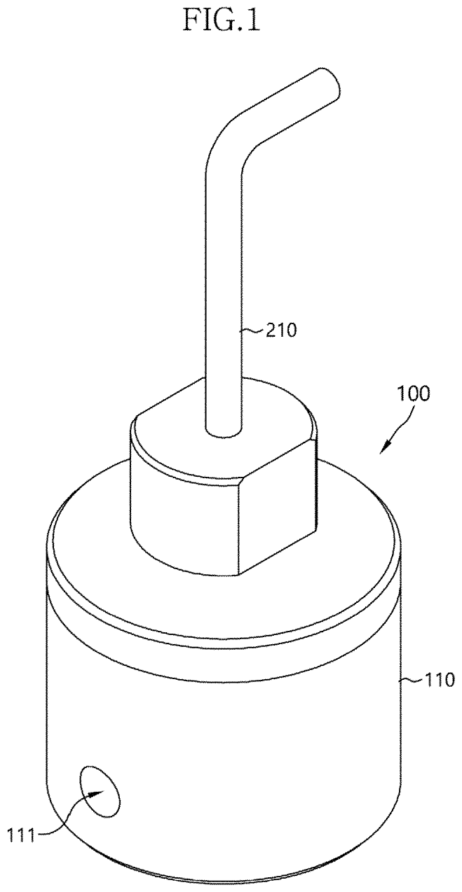

FIG. 1 is a view, illustrating a temperature sensing apparatus, in accordance with example embodiments.

Referring to FIG. 1, a temperature sensing apparatus 100 of this example embodiment may include a body 110. The body 110 may include a tube-combining groove 111. The tube-combining groove 111 may allow for the positioning of a tube through the body 110, combining with the tube, so that an object may flow through the tube, and in turn, the body 110.

The temperature sensing apparatus 100 may include a temperature sensor, which may be arranged in the body 110. A cable 210 may be connected to the temperature sensor. The cable 210 may transmit information, obtained by the temperature sensor, to an external device. The cable 210 may protrude from the body 110.

Alternatively, the temperature sensor and the external device may be electrically connected through a wireless communication.

In example embodiments, the body 110 may have vertically stacked two cylinders. However, the body 110 may be of a shape other than a cylinder.

The body 110 may include fluorine resin, including polyetherether ketone (PEEK), polytetrafluoroethylene (PTFE) and per-fluoro-alkoxy (PFA).

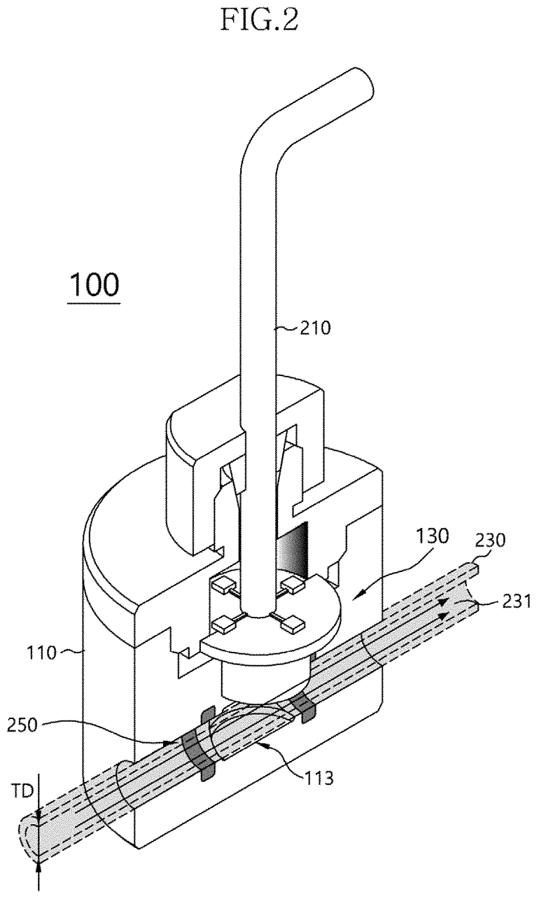

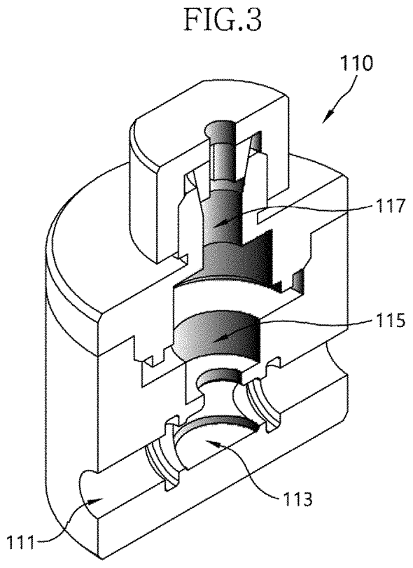

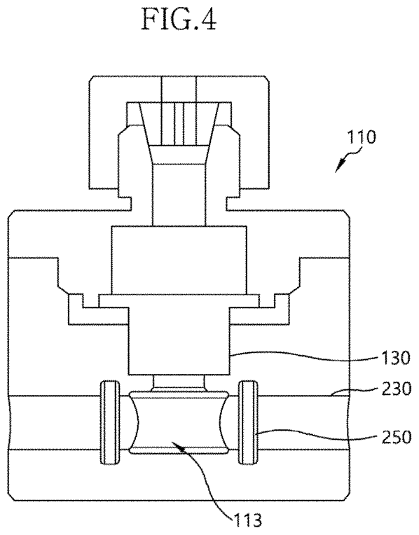

FIG. 2 is a cross-sectional view, illustrating a temperature sensing apparatus combined with a tube, in accordance with example embodiments. FIGS. 3 and 4 are views, illustrating a temperature sensing apparatus, in accordance with example embodiments. FIG. 5 is a view, illustrating a temperature sensing apparatus by tube sizes, in accordance with example embodiments.

Referring to FIG. 2, the temperature sensing apparatus 100 may include the body 110 and the temperature sensor 130. The temperature sensor 130 may measure the temperature of the object 231, which may flow through the tube 230, the tube 230 being combined with the body 110. Therefore, the temperature sensor 130 may measure the temperature of the object 231 in a non-contact manner.

The object 231 may include various chemicals such as DIW, PCW, H₂SO₄, H₂O₂, HF, BOE, H₃PO₄, IPA, etc. However, the object 231 is not restricted to the above-mentioned chemicals. The object 231 may also include mixed chemicals such as SPM (H₂SO₄+H₂O₂), SC1 (H₂O₂+NH4OH+DIW), etc.

Referring to FIG. 3, the body 110 may include the tube-combining groove 111, the air chamber 113 and the temperature sensor-combining groove 115.

The body 110 may include fluorine resin, including polyetherether ketone (PEEK), polytetrafluoroethylene (PTFE) and per-fluoro-alkoxy (PFA).

When the body 110 includes the fluorine resin, fumes may be generated outside of the tube 230 when the chemical, having a high temperature, flows through the tube 230. However, the temperature sensor 130 might not be corroded.

The tube 230 may include PFA. Alternatively, the tube 230 may include a metal such as Stainless Steel (SUS), a resin such as urethane, etc.

The tube-combining groove 111. may be formed in the body 110 so as to insert the tube 230 into the body 110 and have the tube 230 protrude out from both ends of the tube-combining groove 111.

Referring to FIG. 2, the tube-combining groove 111 may be combined with an outer surface of the tube 230 through which the object 231, such as a chemical, may flow in a clamp manner. Since the temperature sensor 130 does not come in contact with the chemical, the temperature sensor 130 and related parts might not be corroded, which means the object 231 might also not be contaminated, avoiding potential accidents caused by contamination.

Further, because the body 110, including the tube-combining groove 111, may be combined with the outer surface of the tube 230, the body 110 and the tube 230 may be combined with each other so that the body 110 and the tube 230 may be replaced efficiently with new parts.

Referring to FIG. 5, a diameter HD of the tube-combining groove 111 may correspond to the diameter TD of the tube 230. For example, the diameter of the tube-combining groove 111 may be substantially ⅛ inch, substantially ¼ inch, substantially ⅜ inch, substantially ½ inch, substantially ¾ inch, substantially 1 inch, etc.

Referring to FIGS. 2 to 4, an air chamber 113 may be arranged adjacent to a temperature sensing region of the object 231.

The air chamber 113 may form an empty space, having a predetermined size based on the size of the tube 230, in the temperature sensing region.

The word “predetermined” as used herein with respect to a parameter, such as a predetermined size, means that a value for the parameter is determined prior to the parameter being used in a process or algorithm. For some embodiments, the value for the parameter is determined before the process or algorithm begins. In other embodiments, the value for the parameter is determined during the process or algorithm but before the parameter is used in the process or algorithm.

When the tube 230 is inserted into the tube-combining groove 111, a vacuum may be formed in the air chamber 113. Thus, the air chamber 113 may isolate the heat emitted from the object 231, flowing through the tube 230, from the heat of the external environment. As a result, the temperature of the object 231 may be accurately measured due to the air chamber 113. That is, the air chamber 113 may function to block the influences of the external temperature.

The air chamber 113 may form a hole between the temperature sensor 130 and the tube 230, inserted into the tube-combining groove 111. Because an obstacle might not exist between the temperature sensor 130 and the tube 230 due to the hole, the temperature sensor 130 may sense the surface temperature of the tube 230.

Further, the air chamber 113 may be connected to a temperature sensor-combining groove 115 and the tube-combining groove 111. The temperature sensor-combining groove 115 may be formed in the body 110. The temperature sensor 130 may be combined with the temperature sensor-combining groove 115.

Referring to FIG. 3, the temperature sensor-combining groove 115, the tube-combining groove 111 and the air chamber 113 may be connected with each other to form the hole.

A cable-combining groove 117 may be formed in the body 110. A cable connected to the temperature sensor 130 may be inserted into the cable-combining groove 117.

When the temperature sensor 130 communicates wirelessly with the external device, the cable-combining groove 117 may be omitted.

The temperature sensor 130 may include an infrared temperature sensor for sensing infrared ray energy, emitted from the object 231, to measure the surface temperature of the object 231. The temperature 130 may also include a resistance temperature sensor for sensing the environment temperature of the temperature sensing region.

The surface temperature of the object 231 may correspond to a temperature obtained by sensing the infrared energy emitted from the tube 230 using the infrared temperature sensor. The infrared temperature sensor may sense the surface temperature of the object 231 using the Fourier formula.

The infrared temperature sensor may be classified into an active type, for radiating an infrared ray to sense a difference of the infrared ray by blocking a light, and a passive type, for sensing a difference of an infrared ray received from an exterior without an emitter.

The environment temperature may include the temperature of the region surrounding the infrared temperature sensor and the temperature of the region surrounding the object. The region, surrounding the infrared temperature sensor, may be substantially the same as the region surrounding the object so that the temperature of the region, surrounding the infrared temperature sensor, may also be substantially the same as the temperature of the region surrounding the object.

For example, after the object 231 flows through the tube 230, the temperature sensor 130 may measure the infrared energy emitted from the object 231. The measured infrared energy may be applied to predetermined conditions to obtain the temperature of the object flowing through the tube 230.

The temperature sensor 130 may apply the surface temperature of the object 231 in the temperature sensing region, the environment temperature of the region surrounding the infrared temperature sensor, the environment temperature of the region surrounding the object 231, and the reference temperature of a sample substantially the same as the object 231 to a correction criteria to calculate the corrected emissivity. The calculated emissivity may be converted into a corresponding temperature to obtain the real temperature of the object 231.

The tube 230 may include a fluorine resin having a very low thermal conductivity, such as PFA. When the temperature of the object 231 in the tube 230 is measured using the non-contact type temperature sensor, the measured temperature of the object 231 may be different from the real temperature of the object 231. For example, when the chemical in the tube 230 of the PFA material has a temperature of about 160° C., a measured temperature on the outer surface of the tube 230 may be 120° C. or lower. Therefore, there may be a discrepancy between the real temperature of the chemical and the temperature of the tube 230 of no less than 40° C.

In order to reduce the discrepancy of the temperatures, the temperature sensor 130 may correct the emissivity sensed from the object 231 by using the reference temperature of the object 231, the environment temperatures, and the correction criteria in conjunction with the surface temperature of the object 231.

Alternatively, after the object 231 flows through the tube 230, the temperature sensor 130 may measure the infrared energy emitted from the object 231. The temperature sensor 130 may then transmit the measured infrared energy to the external device via a wired communication or a wireless communication.

Although not depicted in the drawings, in order to increase an absorption rate of the infrared ray emissivity and to prevent the corrosion of the infrared temperature sensor, the temperature sensor 130 may include a lens made of, for example, sapphire, germanium, etc.

Further, in order to firmly fix the tube 230 to the tube-combining groove 111 and to increase the sealing effect of the air chamber 113, the temperature sensing apparatus 100 may further include an O-ring 250, which may be installed at the tube-combining groove 111 of the air chamber 113.

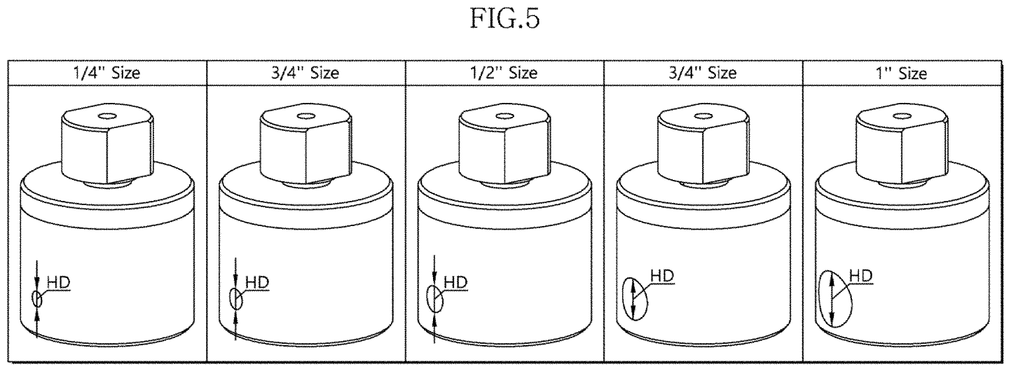

FIG. 6 is a view, illustrating a temperature sensing system, in accordance with example embodiments.

Referring to FIG. 6, the temperature sensing system may include the temperature sensing apparatus 100 and a temperature calculating apparatus 300. The temperature calculating apparatus 300 may receive the temperature information of the object 231 and the peripherals of the object 231, transmitted from the temperature sensing apparatus 100, to measure the real temperature of the object 231.

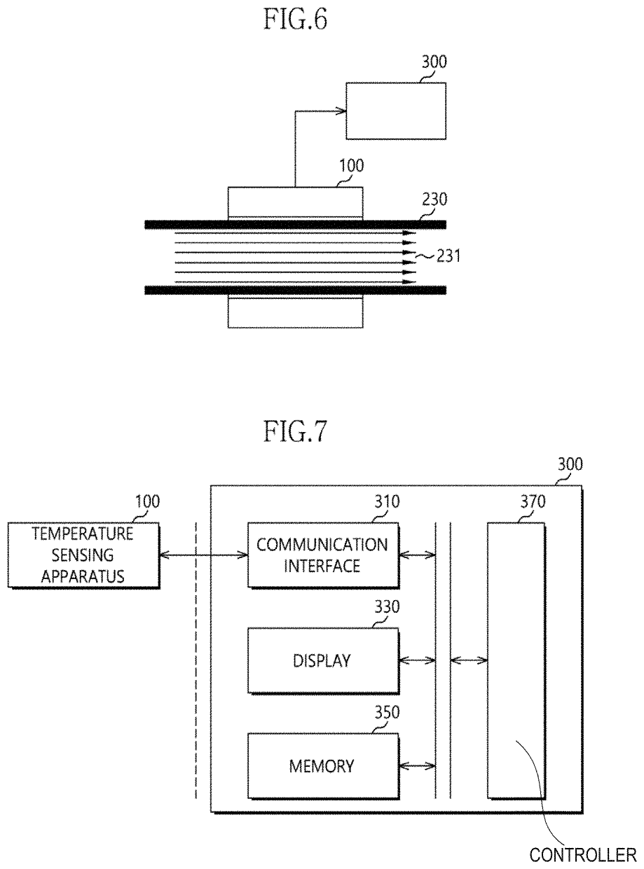

FIG. 7 is a control block diagram, illustrating a temperature sensing system, in accordance with example embodiments.

Referring to FIG. 7, the temperature sensing system may include the temperature sensing apparatus 100 and the temperature calculating apparatus 300.

The temperature sensing apparatus 100 may sense the surface temperature of the object obtained by detecting the infrared energy emitted from the object 231 and the environment temperature of the temperature sensing region.

Referring back to FIG. 2, the temperature sensing apparatus 100 may include the body 110 and the temperature sensor 130. The temperature sensor 130 may sense the temperature of the object 231 in the tube 231.

The body 110 may include the air chamber 113 and the tube-combining groove 111. The air chamber 113 may be positioned adjacent to the temperature sensing region of the object 231. The tube 230 may be combined with the tube-combining groove 111.

The body 110 may further include the temperature sensor-combining groove 115 with which the temperature sensor 130 may be combined.

The air chamber 113 may be connected to the temperature sensor-combining groove 115 and the tube-combining groove 111.

The air chamber 113 may form the empty space, having a predetermined size based on the size of the tube 230, in the temperature sensing region. The temperature sensor-combining groove 115, the tube-combining groove 111 and the air chamber 113 may be connected with each other to form the hole.

The air chamber 113 may form the hole between the temperature sensor 130 and the tube 230.

Referring to FIG. 5, the diameter HD of the tube-combining groove 111 may correspond to the diameter TD of the tube 230. In other words, the correspondence between the diameter of the tube-combining groove 111 and the diameter of the tube 230 may mean that the diameters of the tube-combining groove 111 and the tube 230 may be similar or equal to each other in order to combine the tube 230 with the tube-combining groove 111. For example, the diameter of the tube-combining groove 111 may be about ⅛ inch, about ¼ inch, about ⅜ inch, about ½ inch, about ¾ inch, about 1 inch, etc.

The temperature sensor 130 may include the infrared temperature sensor and the resistance temperature sensor. The infrared temperature sensor may sense the surface temperature of the object 231. The resistance temperature sensor may sense the environment temperatures surrounding the infrared temperature sensor and the object.

The infrared temperature sensor may be classified into an active type, for radiating an infrared ray to sense a difference of the infrared ray by blocking a light, and a passive type, for sensing a difference of an infrared ray received from an exterior without an emitter.

The temperature calculating apparatus 300 may apply the surface temperature of the object 231 and the environment temperatures to the real temperature calculation criteria to obtain the real temperature of the object 231.

The surface temperature of the object may correspond to the temperature, obtained by detecting the infrared energy emitted from the tube 230 through the infrared temperature sensor. The environment temperatures may include the temperature of the region surrounding the infrared temperature sensor and the temperature of the region surrounding the object. The region surrounding the infrared temperature sensor may be substantially the same as the region surrounding the object so that the temperature of the region, surrounding the infrared temperature sensor, may also be substantially the same as the temperature of the region surrounding the object.

Referring to FIG. 7, the temperature calculating apparatus 300 may include a communication interface 310, a display 330, a memory 350, and a controller 370.

The communication interface 310 may communicate with the temperature sensing apparatus 100 in a wired or wireless manner.

The display 330 may display the information of the temperature sensing system as well as the real temperature of the object 231.

The memory 350 may store the information of the temperature sensing system and the reference temperature of the sample, which is substantially the same as the object 231.

The controller 370 may apply the surface temperature of the object 231 in the temperature sensing region, the environment temperature of the region surrounding the infrared temperature sensor, the environment temperature of the region surrounding the object 231, and the reference temperature of a sample substantially the same as the object 231 to a correction criteria to calculate the corrected emissivity. The controller 370 may convert the calculated emissivity into the corresponding temperature to obtain the real temperature of the object 231.

The tube 230 may include fluorine resin, having a very low thermal conductivity such as PFA. When the temperature of the object 231, in the tube 230, is measured using the non-contact type temperature sensor, the measured temperature of the object 231 may be different from the real temperature of the object 231. For example, when the chemical in the tube 230 has a temperature of 160° C., the measured temperature, on the outer surface of the tube 230, may be 120° C. or lower. Therefore, there may be a discrepancy between the real temperature of the chemical and the temperature of the tube 230 of no less than 40° C.

Generally, the infrared temperature sensor may have the emissivity of about 1. According to example embodiments, in order to obtain the real temperature of the object 231 in the tube 230, peripheral environment factors, as well as the tube 230, may be considered in calculating the real temperature of the object 231. Thus, because the emissivity, penetrating through the tube 230, might not be 1, the emissivity may be corrected in the following manner.

The correction criteria of the emissivity in Formula 1, below, may correct temperatures in a section of the object to obtain the accurate temperature of the object in real time.

The surface temperature of the object may be the temperature of the infrared temperature sensor, measured under the condition that the emissivity is approximately 1. The reference temperature may be calculated by directly sensing the sample substantially the same as the object. The reference temperature may be stored in the memory 350.

Particularly, the controller 370 may calculate the corrected emissivity E by using Formula 1.

$$E = \frac{{( {T}_{IR} + 273.15 )}^{4} - {( {T}_{IR - a} + 2 \; 73.15 )}^{4}}{{( {T}_{R} + 273.15 )}^{4} - {( {T}_{O - a} + 273.15 )}^{4}} . \qquad Formula 1$$

In Formula 1, E may indicate the emissivity, T_{IR} may indicate the surface temperature of the object, T_{R} may indicate the reference temperature, T_{IR-a} may represent the environment temperature of the infrared temperature sensor, and T_{O-a} may represent the environment temperature of the object.

For example, when the surface temperature of the object is 50° C., the reference temperature is 60° C., and the environment temperatures of the infrared temperature sensor and the object is 25° C., the controller 370 may obtain an emissivity of about 0.6799 from Formula 1.

Because the environment temperatures of the infrared temperature sensor and the object may correspond to the internal temperature of the air chamber 113, the internal temperature of the air chamber 113 may be 25° C. The environment temperature may be obtained by the resistance temperature sensor.

Further, the controller 370 may apply the surface temperature of the object, the environment temperature of the infrared temperature sensor and the emissivity to the temperature conversion criteria to convert the emissivity into the real temperature of the object.

The above described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications are obvious in view of the present disclosure and are intended to fall within the scope of the appended claims.

What is claimed is:

1. A temperature sensing apparatus comprising:
a body;
and
a temperature sensor configured to measure a temperature of an object, in a tube, without being in contact with the object,
wherein the body includes:
an air chamber formed adjacent to a temperature sensing region of the object; and
a tube-combining groove formed in the body to be combined with the tube.

2. The temperature sensing apparatus of claim 1, wherein the body further comprises
a temperature sensor-combining groove combined with the temperature sensor,
wherein the air chamber is connected to the temperature sensor-combining groove and the tube-combining groove.

3. The temperature sensing apparatus of claim 1, wherein the air chamber forms an empty space, having a predetermined size based on a size of the tube in the temperature sensing region, and
wherein the temperature sensor-combining groove, the tube-combining groove and the air chamber are connected with each other to form a hole.

4. The temperature sensing apparatus of claim 1, wherein a diameter of the tube-combining groove corresponds to a diameter of the tube.

5. The temperature sensing apparatus of claim 1, wherein the body further comprises a cable-combining groove formed in the body to be combined with a cable connected to the temperature sensor.

6. The temperature sensing apparatus of claim 1, wherein the temperature sensor may detect infrared energy emitted from the object, after combining the tube with the tube-combining groove, and
wherein the temperature sensor applies the detected infrared energy to a predetermined criteria to obtain a temperature of the object in the tube.

7. The temperature sensing apparatus of claim 1, wherein the temperature sensor may detect infrared energy emitted from the object, after combining the tube with the tube-combining groove, and
wherein the temperature sensor transmits the detected infrared energy to an external device through a wired or wireless communication.

8. The temperature sensing apparatus of claim 1, wherein the temperature sensor comprises an infrared temperature sensor for detecting infrared energy emitted from the object, to obtain a surface temperature of the object, and a resistance temperature sensor for sensing an environment temperature of the temperature sensing region.

9. The temperature sensing apparatus of claim 1, wherein the body comprises a fluorine resin including polyetherether ketone (PEEK), polytetrafluoroethylene (PTFE) and per-fluoro-alkoxy (PFA).

10. A temperature sensing system comprising:
a temperature sensing apparatus configured to measure a surface temperature of an object, by detecting infrared energy emitting from the object, and to measure an environment temperature of a temperature sensing region; and
a temperature calculating apparatus configured to apply the surface temperature of the object and the environment temperature to a real temperature calculation criteria to calculate a real temperature of the object.

11. The temperature sensing system of claim 10, wherein the temperature sensing apparatus comprises:
a body;
and
a temperature sensor configured to measure a temperature of an object, in the tube, without being in contact with the object,
wherein the body includes:
an air chamber formed adjacent to a temperature sensing region of the object; and
a tube-combining groove formed in the body to be combined with the tube.

12. The temperature sensing system of claim 11, wherein the temperature sensor comprises an infrared temperature sensor configured to measure the surface temperature of the object, and a resistance temperature sensor configured to measure environment temperatures of regions surrounding the infrared temperature sensor and the object.

13. The temperature sensing system of claim 12, wherein the temperature calculating apparatus comprises:
a memory; and
a controller configured to apply the surface temperature of the object detected in the temperature sensing region of the object, the environment temperature of a region surrounding the infrared temperature sensor, the environment temperature of a region surrounding the object, and a reference temperature of a sample, to an emissivity correction criteria to calculate a corrected emissivity, and configured to convert the calculated emissivity into a corresponding temperature to obtain the real temperature of the object,
wherein the sample is substantially the same as the object, and
wherein the reference temperature is stored in the memory.

14. The temperature sensing system of claim 13, wherein the controller calculates the corrected emissivity using a following Formula:
$$E = \frac{{( {T}_{IR} + 273.15 )}^{4} - {( {T}_{IR - a} + 2 \; 73.15 )}^{4}}{{( {T}_{R} + 273.15 )}^{4} - {( {T}_{O - a} + 273.15 )}^{4}} .$$
to wherein the E indicates the emissivity, the T_{IR} indicates the surface temperature of the object, the T_{R} indicates the reference temperature, the T_{IR-a} represents the environment temperature of the infrared temperature sensor, and the T_{O-a} represents the environment temperature of the object.

15. The temperature sensing system of claim 14, wherein the controller applies the surface temperature of the object, the environment temperature of the infrared temperature sensor, and the emissivity to a temperature conversion criteria to convert the emissivity into the real temperature of the object.

16. The temperature sensing system of claim 13, wherein the temperature calculating apparatus further comprises:
a display configured to display information related to the temperature sensing system and the real temperature of the object; and
an interface configured to communicate with the temperature sensing apparatus in a wired or wireless manner.

17. The temperature sensing system of claim 12, wherein the body further comprises a temperature sensor-combining groove combined with the temperature sensor, and
wherein the air chamber is connected to the temperature sensor-combining groove and the tube-combining groove.

18. The temperature sensing system of claim 17, wherein the air chamber forms an empty space having a predetermined size based on a size of the tube in the temperature sensing region, and
wherein the temperature sensor-combining groove, the tube-combining groove and the air chamber are connected with each other to form a hole.

19. The temperature sensing system of claim 17, wherein the air chamber forms a hole between the temperature sensor and the tube that is inserted into the tube-combining groove.

20. The temperature sensing system of claim 17, wherein a diameter of the tube-combining groove corresponds to a diameter of the tube.
